(19) United States
(12) Patent Application Publication
(10) Pub. No.: US 2020/0024492 A1
(43) Pub. Date: Jan. 23, 2020

(54) USING MAGNETIC FIELDS TO INCREASE THE BONDING AREA OF AN ADHESIVE JOINT

(71) Applicant: Apple Inc., Cupertino, CA (US)

(72) Inventors: John C. DIFONZO, Emerald Hills, CA (US); Tyler J. EWING, San Francisco, CA (US); Nathan MORRIS, Los Gatos, CA (US); David S. HERMAN, San Francisco, CA (US)

(21) Appl. No.: 16/194,153

(22) Filed: Nov. 16, 2018

Related U.S. Application Data
(60) Provisional application No. 62/701,417, filed on Jul. 20, 2018.

(51) Int. Cl. C09J 9/00; C09J 11/04; C09J 5/06; H05K 5/00; H05K 1/18; H05K 3/30

(52) U.S. Cl. CPC C09J 9/00; C09J 11/04; C09J 5/06; H05K 2203/104; H05K 1/181; H05K 5/0017; H05K 3/305; H05K 5/0086

(57) ABSTRACT

This application relates to an assembly technique for joining parts using a magnetic adhesive. A liquid adhesive including magnetic particles is provided, the liquid adhesive having sufficient properties that allow the adhesive to flow under the influence of a magnetic field prior to curing. A method for joining parts includes the steps of applying an adhesive to a substrate at a location corresponding to the joint, placing a magnetic element proximate the joint to generate a magnetic field that interacts with the magnetic particles in the adhesive to cause the adhesive to flow in a direction corresponding to the magnetic field, and curing the magnetic adhesive under the influence of the magnetic field. An assembly fixture for joining parts includes a magnetic element and, optionally, an inductive heating element. The assembly technique can be used to form a housing of an electronic device from two or more components.

### CROSS-REFERENCE TO RELATED APPLICATIONS

The present application claims the benefit of U.S. Provisional Application No. 62/701,417, entitled “USING MAGNETIC FIELDS TO INCREASE THE BONDING AREA OF AN ADHESIVE JOINT,” filed Jul. 20, 2018, the content of which is incorporated herein by reference in its entirety for all purposes.

### FIELD

The described embodiments relate generally to magnetic adhesives. More particularly, the present embodiments relate to magnetic particles dispersed within an adhesive and techniques related to using a magnetic field to influence the distribution of the adhesive during the assembly of two or more components.

### BACKGROUND

Various techniques are implemented when assembling components to form an apparatus. For example, components can be assembled using mechanical fasteners, welds, mechanical interference, or adhesives. Lots of research has gone into studying various adhesives. Engineers exert significant effort selecting the right adhesive to provide the best qualities for a particular application. For example, strength, color, viscosity, flexibility, cure time, and other characteristics may be considered when selecting a proper adhesive for a given application.

Nevertheless, applying the adhesive during assembly can prove difficult in some situations. An assembler might have difficulty applying the adhesive in a particular joint uniformly from one unit to the next unit. Low viscosity adhesives may tend to run away from the intended joint, thereby resulting in a weak bond. High viscosity adhesives might be difficult to dispense. Improvements to techniques related to applying adhesives are desired.

### SUMMARY

This paper describes various embodiments that relate to techniques for influencing the flow of a liquid substance using magnetic fields. Magnetic particles are dispersed in a liquid that has characteristics such that motion imparted to the magnetic particles causes the liquid to flow with the magnetic particles. The exemplary characteristics of the liquid can depend on a variety of factors including a particle size and shape and the viscosity of the liquid. The magnetic properties of the liquid substance can then be exploited during assembly of various products that use these substances.

A method is disclosed for applying adhesive to a joint formed between a substrate and a component. The method includes the steps of: applying an adhesive, which includes magnetic particles dispersed therein, to a substrate at a location corresponding to the joint, placing a fixture including a magnetic element proximate the joint to generate a magnetic field that interacts with the magnetic particles in the adhesive to cause the adhesive to flow in a direction corresponding to the magnetic field, and curing the adhesive under the influence of the magnetic field.

In some embodiments, the fixture can be removed once the adhesive reaches a gel point. In other embodiments, the fixture can be removed after a period of time that is sufficient to allow the adhesive to transition from a liquid state to a solid state.

In some embodiments, a strength of the magnetic field generated by the magnetic element is adjusted to select a desired shape of the adhesive at the joint. For example, the strength of the magnetic field can be modulated to change a shape (e.g., a radius) of a fillet formed by the adhesive at the joint on one or both sides of the component.

In some embodiments, the magnetic element is a permanent magnet. In other embodiments, the magnetic element is an electromagnet.

In some embodiments, the fixture includes an inductive heating element. In such embodiments, curing the adhesive can include heating the magnetic particles in the adhesive using an inductive heating element.

In some embodiments, the substrate and the component are ferromagnetic. In other embodiments, the substrate is non-ferromagnetic and the component is ferromagnetic. In yet other embodiments, neither the substrate nor the component are ferromagnetic.

A housing for an electronic device can be formed using an adhesive bond to join at least two components. The housing can include a first component and a second component bonded to the first component by a magnetic adhesive to form a joint between the first component and the second component. A shape of the magnetic adhesive, as cured at the joint, is based on a magnetic field imparted at the joint during assembly while the magnetic adhesive cures.

An assembly fixture is described for adhesively joining two components to form a housing of an electronic device. The assembly fixture includes a magnetic element configured to be placed proximate a joint between a first component and a second component. The magnetic element generates a magnetic field at a location corresponding to the joint. The joint includes a magnetic substance in a liquid state such that the magnetic substance flows relative to at least one of the first component or the second component under the influence of an attractive force imparted on the magnetic substance by the magnetic element.

In some embodiments, the magnetic element is a permanent magnet. In other embodiments, the magnetic element is an electromagnet comprising a coil surrounding a ferromagnetic core. In some embodiments, the assembly fixture also includes an inductive heating element that is activated to cure the magnetic substance under the influence of the magnetic field.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The disclosure will be readily understood by the following detailed description in conjunction with the accompanying drawings, wherein like reference numerals designate like structural elements.

FIG. 1 illustrates an adhesive, in accordance with some embodiments.

FIGS. 2A-2D illustrate an assembly process for adhesively bonding a component to a substrate, in accordance with some embodiments.

FIGS. 3A-3B illustrate techniques for adjusting a shape of the adhesive surrounding the joint, in accordance with some embodiments.

FIG. 4 illustrates a technique for forming an adhesive joint, in accordance with some embodiments.

FIG. 5 illustrates a technique for curing a magnetic adhesive, in accordance with some embodiments.

FIGS. 6A-6B illustrate a multi-layered adhesive joint, in accordance with some embodiments.

FIGS. 7A-7B illustrate an application for moving a magnetic adhesive into a joint, in accordance with some embodiments.

FIG. 8 illustrates a portable electronic device, in accordance with some embodiments.

FIGS. 9A-9B illustrate a laptop computer that utilizes a fastener free securing mechanism, in accordance with some embodiments.

FIG. 10 is a flowchart of a method for forming an adhesive bond at a joint between components of a housing for an electronic device, in accordance with some embodiments.

FIG. 11 is a flowchart of a method for influencing a magnetic substance using a magnetic field, in accordance with some embodiments.

### DETAILED DESCRIPTION

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

A liquid adhesive is disclosed that includes ferromagnetic particles dispersed therein. A size and geometry of the ferromagnetic particles is carefully selected and matched with a given adhesive such that the adhesive, under the influence of a magnetic field, flows towards the source of the magnetic field. In some embodiments, the magnetic field is provided to cause the adhesive to be pulled up the side of a component being bonded to a substrate. The adhesive forms a natural fillet under the influence of the magnetic field and a gravitational field that, after the adhesive cures, provides a strong adhesively bonded joint. The shape of the cured adhesive formed using the magnetic field, is a shape that cannot be naturally achieved with conventional adhesives or application techniques.

Other applications that can benefit from a magnetic adhesive such as that described herein are bonding joints that are difficult to access or filling gaps between components to create a seal proximate an opening in a housing of an electronic device, such as by using the magnetic adhesive to create a cosmetic seal or seam. Another application is utilizing the magnetic adhesive for staking large components such as capacitors to a printed circuit board (PCB). Another application is utilizing the magnetic adhesive for potting (e.g., water-proofing electronic components). Some magnetic adhesives can include a significant percentage of conductive particles such that the adhesive is conductive. Such adhesives can then be used for electro-magnetic interference (EMI) shielding applications or for connecting electrical components to contacts on a PCB.

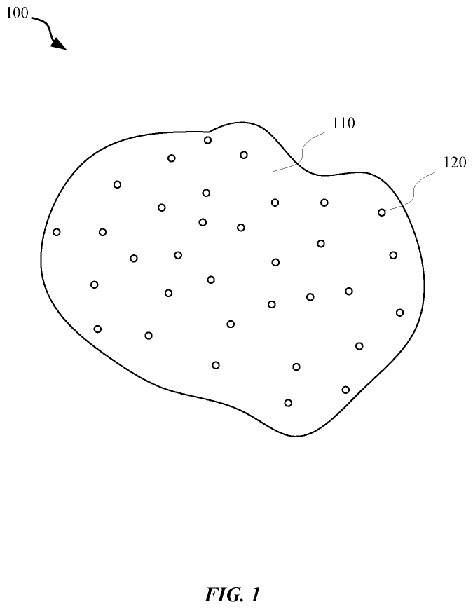

These and other embodiments are discussed below with reference to FIGS. 1-9; however, those skilled in the art will readily appreciate that the detailed description given herein with respect to these figures is for explanatory purposes only and should not be construed as limiting.

FIG. 1 illustrates an adhesive 100, in accordance with some embodiments. The adhesive 100 includes a liquid adhesive 110 in an uncured state. In various embodiments, the liquid adhesive 110 can be, but is not limited to, one of the following types of adhesive: epoxies (single-part and multi-part), cyanoacrylates, urethanes, or acrylic adhesives. The liquid adhesive 110 has various characteristics including viscosity, cohesive strength, elastic modulus, and cure conditions (e.g., thermosetting, requiring hardener, cure time, etc.). In some embodiments, the liquid adhesive 110 can be referred to as a non-magnetic liquid polymer. The adhesive characteristics can be adjusted to achieve a desired property for a given application. For example, a low viscosity adhesive can be used in one application and a high viscosity adhesive can be used in another application.

The adhesive 100 also includes magnetic particles 120 dispersed within the liquid adhesive 110. In some embodiments, the magnetic particles 120 are ferromagnetic particles such as particles of a 410 series stainless steel. It will be appreciated that the magnetic particles 120 can be produced from any ferromagnetic material such as steel, ferrite, neodymium alloys (e.g., NdFeB) or other rare earth alloys exhibiting magnetic qualities, as well as other ferrous metals or alloys of the same. In other embodiments, the magnetic particles 120 can be produced from any paramagnetic material or diamagnetic material rather than ferromagnetic material. In the case of paramagnetic material, the magnetic forces will be weaker than compared to ferromagnetic material. In the case of diamagnetic material, the magnetic forces will repel the magnetic particles 120 rather than attract the magnetic particles 120. Although the remainder of this specification may refer to ferromagnetic material exclusively, other embodiments can alternatively implement the magnetic particles 120 as paramagnetic material or diamagnetic material.

In some embodiments, the magnetic particles 120 are irregularly shaped. For example, the magnetic particles 120 may have a first dimension (e.g., length) that is many times larger than a second dimension (e.g., width). For example, the magnetic particles 120 can have lengths greater than 100 microns and thicknesses less than 25 microns. These irregularly shaped particles can be referred to as metal flakes. The shape of the metal flakes can be conducive to moving with the liquid adhesive 110 under the influence of a magnetic field. More specifically, the metal flakes have a larger surface area for cohesively bonding with the polymers in the liquid adhesive 110 such that the metal flakes do not move easily through the fluid, and the larger cross-section of the flakes in at least one direction is beneficial for imparting momentum to the liquid adhesive 110.

In some embodiments, the magnetic particles 120 are substantially spherical in shape. In yet other embodiments, the magnetic particles 120 can include a non-magnetic core, such as glass or ceramic, coated in a ferromagnetic material. In some embodiments, the magnetic particles 120 can have a hollow core, such as hollow glass beads coated in a ferromagnetic material.

In some embodiments, the magnetic particles 120 are substantially uniform in size. For example, the magnetic particles 120 can have a diameter of 50 microns and a tolerance of plus-minus 5 microns. In other embodiments, the magnetic particles 120 are non-uniform in size. For example, some magnetic particles 120 have a large diameter of 250 microns and other magnetic particles 120 have a small diameter of 100 microns, less than half of the larger diameter. In some embodiments, the ferromagnetic particles are interspersed with additional non-ferromagnetic particles of a different material, such as aluminum or copper. The non-ferromagnetic particles can aid in improving the conductivity of the adhesive while the ferromagnetic particles aid in promoting adhesive flow under the influence of a magnetic field.

The adhesive 100, which includes liquid adhesive 110 and magnetic particles 120, can be referred to herein as magnetic adhesive 100. It will be appreciated that the magnetic particles 120 can be acted on under the influence of a magnetic field. The magnetic particles 120 will align with the magnetic field and experience an attractive force based on the magnetic field. This attractive force will cause motion in the magnetic particles 120 that will cause the adhesive 100 to flow according to the magnetic field as well as any other forces acting on the liquid adhesive 110 (e.g., gravity, capillary force, pressure differentials, etc.). The effectiveness of the flow rate will depend on the viscosity of the liquid adhesive 110, cohesive strength (e.g., how well the liquid adhesive 110 bonds to the magnetic particles 120), a size of the magnetic particles 120, and a concentration of magnetic particles 120 within the liquid adhesive 110 as well as a strength and shape of the applied magnetic field, among other characteristics. These characteristics can be adjusted to cause the adhesive to flow predictably in response to an applied magnetic field, and the flow and resulting shape of the cured adhesive 100 can increase the bond strength and/or structural strength of certain adhesive joints.

In some exemplary embodiments, the size of the magnetic particles 120 is less than 150 micrometers in diameter and a viscosity of the liquid adhesive is between 10,000 and 30,000 centipoise (cP). It will be appreciated that the exemplary size and shape of the particles and/or the viscosity of the liquid can be determined by applying Stokes' law. The aforementioned characteristics are merely provided as exemplary characteristics for some applications, and magnetic adhesives outside of these limiting characteristics are contemplated as being within the scope of the present disclosure. A concentration of the magnetic particles 120 in the magnetic adhesive 100, by weight, can be less than 20 percent by weight. In other exemplary embodiments, the concentration of the magnetic particles 120 can be sufficient to make the adhesive 100 electrically conductive. For example, a concentration by weight of 80 percent by weight or higher may be sufficient to make the adhesive 100 electrically conductive while still retaining sufficient adhesive bonding strength.

In some embodiments, the size of the magnetic particles 120 is selected to be greater than a minimum bond length associated with the liquid adhesive 110. More specifically, adhesives can require a minimum separation distance between two surfaces being bonded in order for the polymers to create the adhesive bond. The diameter of the magnetic particles 120 can be selected to be greater than this minimum bond length to ensure that the separation of the two surfaces being bonded by the liquid adhesive 110 is greater than the diameter of the magnetic particles 120.

In some embodiments, the techniques described herein can be practiced with any liquid that has characteristics that facilitate the flow of the liquid responsive to movement of the magnetic particles 120. For example, the techniques described herein can be practiced with a silicone (e.g., polysiloxanes) having magnetic particles 120 dispersed therein. Any liquid that will move with the magnetic particles 120 and can be caused to transition to a semi-solid state or a solid state is capable of being utilized in the manner described below.

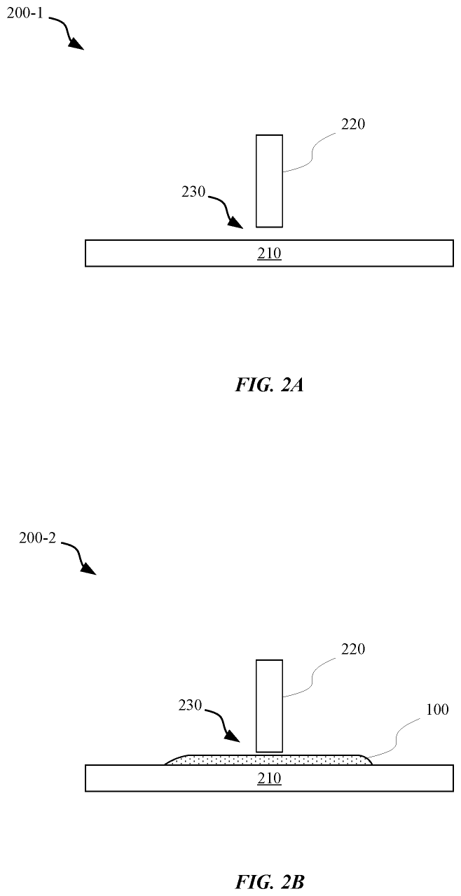

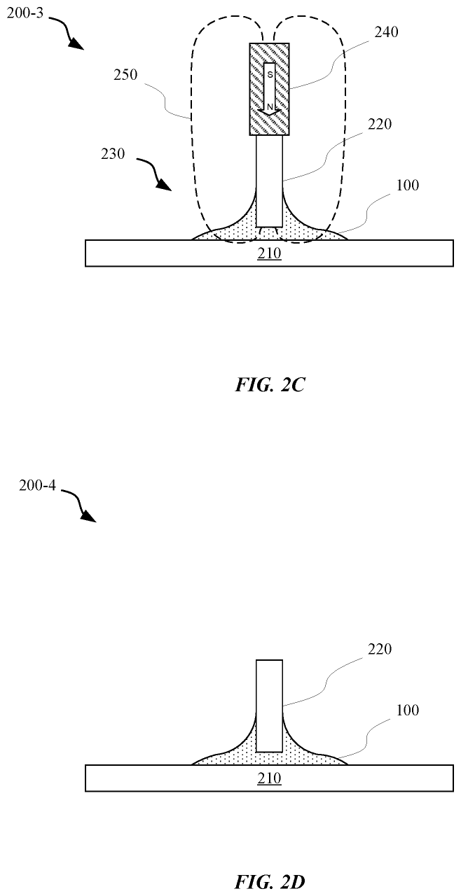

FIGS. 2A-2D illustrate an assembly process 200 for adhesively bonding a component to a substrate, in accordance with some embodiments. In a first step 200-1 of the process 200, as depicted in FIG. 2A, a substrate 210 and a component 220 are provided to form an adhesive bond at a joint 230 between the substrate 210 and the component 220. In some embodiments, the joint 230 is a T-joint, although, in other embodiments, the joint 230 can be a butt joint, lap joint, or any other type of technically feasible joint.

The substrate 210 and the component 220 being adhesively joined to the substrate 210, can be a similar material or different materials. In some embodiments, one or both of the substrate 210 and the component 220 can be a ferromagnetic material such as steel. In other embodiments, neither the substrate 210 nor the component 220 is ferromagnetic. Examples of non-ferromagnetic materials include metals (e.g., aluminum alloys, 300 series stainless steels, copper, etc.), plastics (e.g., PE, PTFE, etc.), ceramics (e.g., glass, enamels, etc.), or composites such as carbon or glass fibers encased in resin, plastic coated metals, metals with inlayed plastic or glass, and the like.

In a second step 200-2 of the process 200, as depicted in FIG. 2B, a magnetic adhesive 100 is dispensed proximate the joint 230. Although the magnetic adhesive 100 includes magnetic particles 120 dispersed therein, the magnetic particles 120 are not magnetized during this step in the process. Consequently, the magnetic particles 120, and, therefore, the adhesive 100, are not attracted to the substrate 210 or the component 220.

The liquid adhesive 110 in the magnetic adhesive 100 will flow due to natural forces such as gravity, capillary forces, and pressure differential to spread out on the substrate 210 in and/or around the joint 230. It will be appreciated that the adhesive 100 can be dispensed manually or automatically. For example, an assembly technician can manually brush the magnetic adhesive 100 on the substrate 210, or the assembly technician can manually dispense, through a syringe, the magnetic adhesive 100 onto the substrate 210. Alternatively, a robot can automatically dispense the magnetic adhesive 100 through a nozzle, through a screen-printing process, or the like.

In a third step 200-3 of the process 200, as depicted in FIG. 2C, a magnet 240 is placed proximate the joint 230. The magnetic field 250 generated by the magnet 240 causes the magnetic particles 120 in the magnetic adhesive 100 to align with the magnetic field. The magnetic particles 120 experience an attractive force with the magnet 240 that is used to influence the shape of the magnetic adhesive 100 in and surrounding the joint 230. For example, as shown in FIG. 2C, the magnetic adhesive 100 creeps up the sides of the component 220 on either side of the joint 230 to create a fillet (e.g., a rounded transition) of magnetic adhesive 100 on either side of the joint 230.

In the example shown in FIG. 2C, the component 220 is ferromagnetic while the substrate 210 is non-ferromagnetic. Consequently, the ferromagnetic component 220 influences the shape of the magnetic field 250 and affects the shape of the magnetic adhesive 100 at the joint 230. In other examples, the component 220 and the substrate 210 are non-ferromagnetic and, therefore, the shape and/or strength of the magnetic field 250 proximate the joint 230 is different, thereby influencing a different shape of the magnetic adhesive 100 at the joint 230. In yet other embodiments, both the substrate 210 and the component 220 are ferromagnetic, which will further affect the shape and/or strength of the magnetic field 250 proximate the joint 230.

In some embodiments, the magnet 240 is replaced with a fixture including a magnetic element capable of generating a magnetic field proximate the joint 230. For example, a fixture can include a conducting coil wrapped around a ferromagnetic core to form an electromagnet. A current can be applied to the coil to generate a magnetic field similar to the permanent magnet 240 of FIG. 2C. The current can be controlled to change the strength of the magnetic field and, therefore, control the shape and/or strength of the magnetic adhesive 100 at the joint 230. Alternatively, the fixture can include the magnet 240 as well as one or more other components such as clamps, location pins, and/or an inductive heating element, as described more fully below.

In a fourth step 200-4 of the process 200, as depicted in FIG. 2D, the magnetic adhesive 100 is allowed to cure. The magnet 240 remains proximate the joint 230 while the magnetic adhesive 100 cures, thus maintaining the shape of the magnetic adhesive 100 at the joint 230 until the magnetic adhesive 100 has cured sufficiently that the shape is maintained when the magnet 240 is removed. In some embodiments, the magnet 240 remains proximate the joint 230 until the magnetic adhesive 100 reaches a gel point of the liquid polymer in the liquid adhesive 110 that is sufficient to maintain the shape of the magnetic adhesive 100 without the influence of the magnetic field. In other words, the magnet 240 is kept in place proximate the joint 230 until the liquid adhesive 110 undergoes a state transition from a liquid to a gel or solid, the transition characterized by a significant change in viscosity of the liquid adhesive 110. In some embodiments, curing the liquid adhesive 110 can include waiting for a prescribed time for the liquid adhesive 110 to set (e.g., for a chemical reaction between two components of the adhesive to cause the adhesive to harden). In other embodiments, curing the liquid adhesive 110 can include heating the liquid adhesive 110 or subjecting the liquid adhesive 110 to UV light to cure the liquid adhesive 110.

It will be appreciated that the steps of process 200 can be performed in a different order. For example, the magnetic adhesive 100 can be applied to the substrate 210 prior to introducing the component 220 to the substrate 210. As another example, the magnet 240 can be placed proximate the joint 230 prior to the magnetic adhesive 100 being dispensed at the joint 230. For example, the magnet 240 could be placed proximate the substrate 210 prior to the magnetic adhesive 100 being dispensed on the substrate 210. The magnetic field could cause the magnetic adhesive 100 to move prior to the component 220 being introduced to the substrate 210, which is beneficial in guiding the magnetic adhesive 100 to the correct location prior to forming the joint 230 between the substrate 210 and the component 220. This technique might be particularly useful for pulling adhesive into an area that is traditionally difficult to reach with a dispensing mechanism.

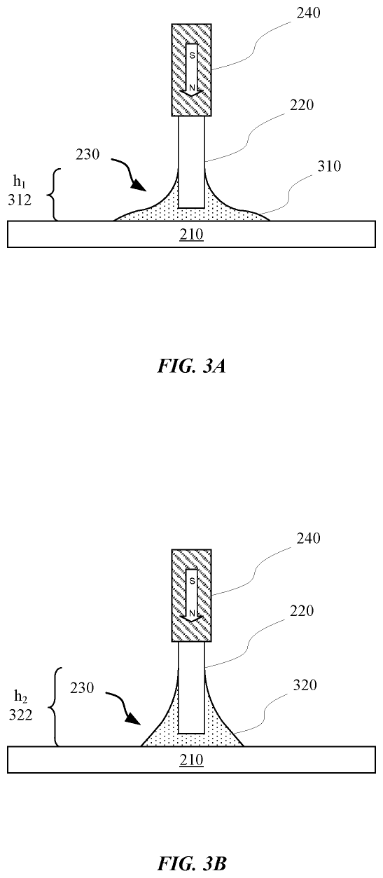

FIGS. 3A-3B illustrate techniques for adjusting a shape of a magnetic adhesive surrounding a joint 230, in accordance with some embodiments. As depicted in FIG. 3A, a first adhesive 310, which includes a liquid adhesive and magnetic particles, is dispensed at the joint 230 and subjected to a magnetic field from the magnet 240. The first adhesive 310 creeps up the sides of the component 220 to a height h₁ 312. In contrast, as depicted in FIG. 3B, a second adhesive 320, which includes a liquid adhesive and magnetic particles, is dispensed at the joint 230 and subjected to the magnetic field from magnet 240. The second adhesive 320 creeps up the sides of the component 220 to a height h₂ 322, which is larger than height h₁ 312.

It will be appreciated that shape of the cured adhesive surrounding the joint 230 can be tailored by changing the characteristics of the liquid adhesive. For example, the first adhesive 310 can be more viscous than the second adhesive 320. Increased viscosity can inhibit the movement of the adhesive under the influence of a particular magnetic field. Other characteristics that can affect the shape of the adhesive at the joint 230 include: adjusting a concentration of magnetic particles in the adhesive; changing the material of the magnetic particles; adjusting a formula of the adhesive (e.g., different polymers or adhesive types can exhibit different cohesive strength, viscosity, etc.); and the like.

In addition to changing the characteristics of the adhesive, the shape of the adhesive in the joint 230 can be affected by changing the magnetic field proximate the joint 230. For example, where the first adhesive 310 and the second adhesive 320 are structurally the same adhesive, the shape of the adhesive at the joint can be changed by changing the strength of the magnet 240. A weaker magnetic field applied to the first adhesive 310 can result in creep to the first height h₁ 312, while a stronger magnetic field applied to the second adhesive 320, that is the same as the first adhesive 310, can result in creep to the second height h₂ 322.

It will also be appreciated that the shape can be changed by changing a concentration of ferromagnetic material in the component 220 and/or the substrate 210, as this will have an effect on the shape of the resulting magnetic field proximate the joint 230. In other words, any ferromagnetic material placed proximate the joint 230 will affect the magnetic flux around the joint 230 and, therefore, affect the strength and/or orientation of the magnetic field experienced by the magnetic particles in the liquid adhesive.

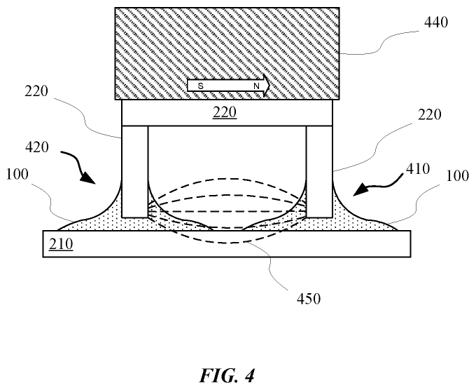

FIG. 4 illustrates a technique for forming an adhesive joint, in accordance with some embodiments. It will be appreciated that multiple adhesive joints can be formed substantially simultaneously. For example, two T-joints can be formed substantially simultaneously by arranging multiple ferromagnetic components 220 to form an equivalent of a horseshoe magnet. As depicted in FIG. 4, the magnet 440 is placed proximate the components 220, but the polarity of the magnetic dipole of the magnet 440 is arranged parallel to a surface of the substrate 210. This causes the ferromagnetic components 220 to form a magnetic circuit similar to a horseshoe magnet, resulting in a magnetic field 450 directed between the two ends of the ferromagnetic components 220 proximate the two T-joints, joint 410 and joint 420.

In some embodiments, the magnetic adhesive 100 is dispensed on the substrate under both the first joint 410 and the second joint 420 prior to the magnet 440 being placed in proximity to the joints. The magnet 440 then causes the adhesive to creep up the components 220 at each of the joints as depicted in FIG. 4. In other embodiments, the magnetic adhesive 100 is dispensed proximate one joint and allowed to flow to the other joint prior to applying the magnetic field. Although not shown explicitly in FIG. 4, a second magnet can be placed proximate the first joint 410 and/or the second joint 420, on an opposite side of the substrate 210 relative to the magnet 240, to aid in flowing adhesive 100 from one joint to the other joint. The second magnet can then be removed and the primary magnet 240 can be placed proximate the joint to facilitate the adhesive moving toward the component to increase a strength of the joint.

It will be appreciated that use of low viscosity adhesives and then subsequent application of a magnetic field can enable adhesion of joints that are hard to access using conventional techniques. For example, during assembly, it may be possible to access joint 410 to dispense the magnetic adhesive 100, but access to joint 420 is not possible (e.g., due to being in an interior area of the assembly). Conventional means for forming an adhesive bond at joint 420 may include applying the adhesive prior to bringing component 220 proximate the substrate 210. However, this technique typically causes the adhesive to flow outward away from the joint prior to the joint being formed, thereby weakening the adhesive bond between the component 220 and the substrate 210. The technique using a magnetic and low viscosity adhesive enables dispensing of the adhesive at one location, such as joint 410, and subsequently moving the adhesive to a second location before being influenced into the final position of the adhesive joint due to the magnetic field. This technique wastes less adhesive and/or results in a stronger adhesive bond than conventional techniques.

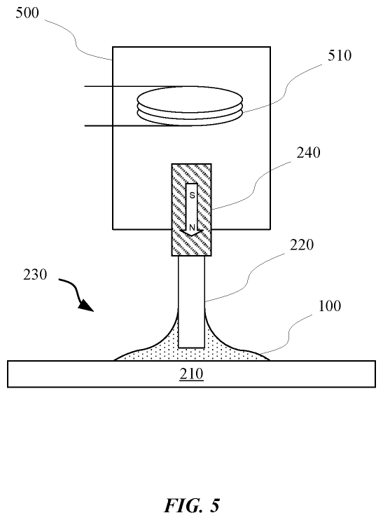

FIG. 5 illustrates a technique for curing a magnetic adhesive, in accordance with some embodiments. It will be appreciated that the magnetic adhesive 100 includes a liquid adhesive 110 and magnetic particles 120. Furthermore, some types of adhesives are cured at high temperatures, which can be referred to as thermosetting adhesives. However, care may need to be exercised when curing these adhesives not to damage the substrate 210 and/or components 220.

In some embodiments, the substrate 210 and the components 220 are formed from materials such as plastics. Applying heat to the assembly to cure the adhesive 100 could cause deformation or discoloration of the substrate 210 and/or components 220. Consequently, it is desired to be able to heat the adhesive without heating the surrounding bodies. Due to the nature of the magnetic particles 120 in the magnetic adhesive 100, an induction heating technique can be employed to heat the magnetic particles 120, thereby supplying heat to the liquid adhesive 110 that causes the liquid adhesive 110 to cure (e.g., set), without heating the substrate 210 and the component 220.

As depicted in FIG. 5, an induction heating element 510 can be included in a fixture 500 along with the magnet 240. The induction heating element 510 can comprise a conductive coil capable of transmitting high current through the coil to generate a fluctuating magnetic field external to the coil. Once the magnetic adhesive 100 takes shape under the influence of the magnetic field from the magnet 240, the induction heating element 510 can be activated to heat up the magnetic particles 120 in the magnetic adhesive 100, thereby curing the liquid adhesive 110. It will be appreciated that the induction heating element 510 does not generate heat in the substrate 210 or the component 220, when the substrate 210 and component 220 are made from such materials that are incompatible with induction heating (e.g., plastics, some metals, etc.).

While heat generated in the magnetic particles 120 conducts through the liquid adhesive 110 to the substrate 210 and/or component 220, the thermal conductivity of the liquid adhesive 110 can be much less than the thermal conductivity of the substrate 210 and/or the component 220. Therefore, the heat is dissipated in the substrate 210 and/or component 220 at a faster rate than heat is transferred from the liquid adhesive 110 to the surrounding bodies, which prevents the substrate 210 and/or component 220 from experiencing a rise in temperature to a point that could damage the substrate 210 and/or component 220.

In some embodiments, the induction heating element 510 can be utilized independently from the magnet 240. In other words, the technique for utilizing an induction heating element 510 to cure an adhesive including particles dispersed therein that are compatible with generating heat in response to a fluctuating magnetic field can be implemented separately from utilizing a magnetic field to facilitate motion or flow of the adhesive to influence a shape of the cured adhesive.

In yet other embodiments, the fixture 500 can be used in a disassembly process subsequent to the assembly process described above. After the adhesive 100 has cured, the inductive heating element can be used to heat up the magnetic particles 120, thereby damaging the adhesive bonds in the cured adhesive and allowing the joint to be disassembled.

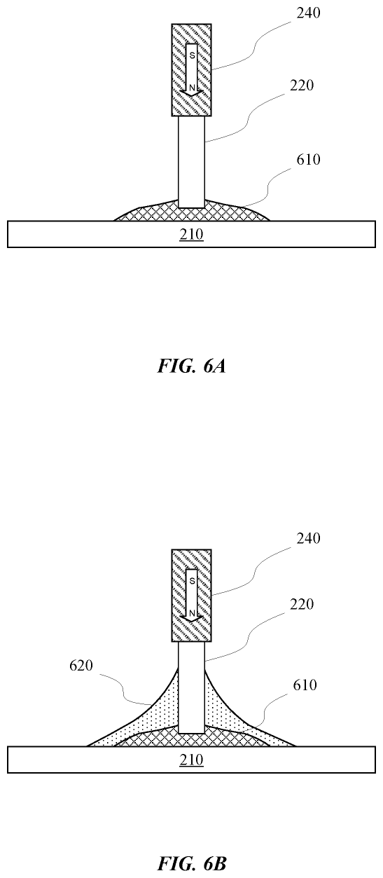

FIGS. 6A-6B illustrate a multi-layered adhesive joint, in accordance with some embodiments. In some embodiments, an adhesive bond can be formed in a joint using two or more adhesives. It will be appreciated that a low viscosity adhesive can be more conducive to filling a tight joint and forming a bond between the substrate 210 and the component 220. However, a low viscosity adhesive may not form the correct shape of the adhesive bond surrounding the joint, and/or the adhesive bond could interfere with the fit of other components proximate the joint. Consequently, a multi-layered adhesive bond can be formed at the joint using two or more different adhesives.

For example, as depicted in FIG. 6A, a first adhesive 610 having a low viscosity can be applied at the joint. A magnet can be placed proximate the joint and the first adhesive 610 is allowed to cure, forming an adhesive bond at the joint of a first shape. As depicted in FIG. 6B, a second adhesive 620 having a higher viscosity can be applied at the joint. A magnet can be placed proximate the joint and the second adhesive 620 is allowed to cure, forming an adhesive bond at the joint of a second shape that overlays the first shape of the first adhesive 610. It will be appreciated that different magnets 240 can be applied for the first step of forming the adhesive bond with the first adhesive 610 and the second step of forming the adhesive bond with the second adhesive 620, thereby forming different shapes according to two different magnetic fields. Alternatively, an electromagnet can be placed proximate the joint and different magnetic field strengths can be induced in the electromagnet by applying different currents to the electromagnet to form a desired shape of the first adhesive 610 and the second adhesive 620.

It will be appreciated that the first adhesive 610 can be utilized to facilitate a better adhesive bond between the components while the second adhesive 620 can be utilized to provide a final shape of the joint, which provides additional structural strength due to the physical shape of the joint. Utilizing the second adhesive 620 to form the final shape of the joint without the first adhesive 610 could be problematic in some cases where the properties of the adhesive necessary to create the final desired shape of the joint are not conducive to forming a strong adhesive bond between the component and the substrate.

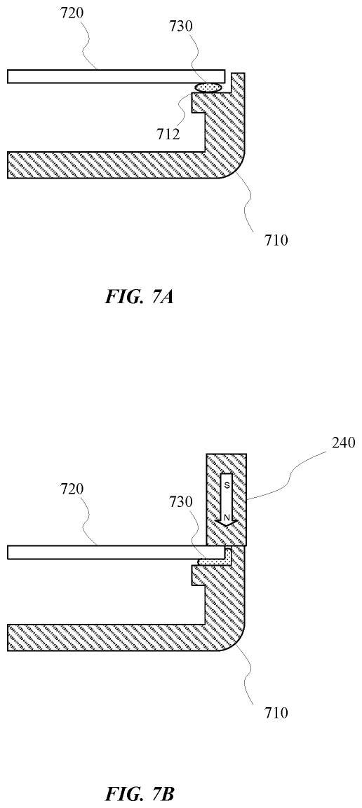

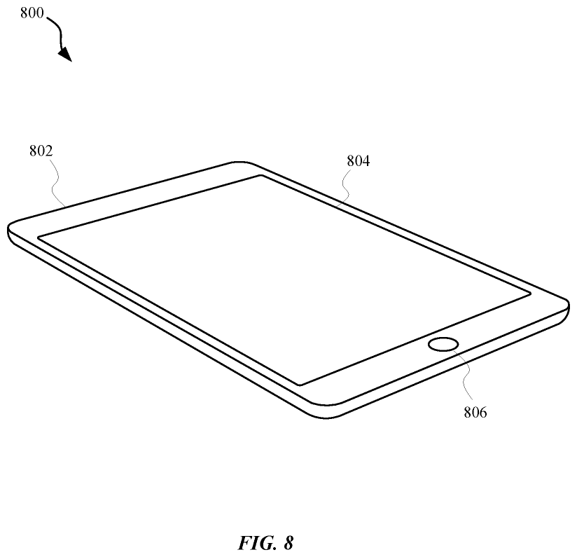

FIGS. 7A-7B illustrate an application for moving a magnetic adhesive 100 into a joint, in accordance with some embodiments. It will be appreciated that the magnetic field is not only useful for creating a shaped adhesive bond at a joint, such as by forming a fillet on one or both sides of a T-joint, but can also be utilized to achieve other beneficial results. For example, as depicted in FIG. 7A, a conventional lap joint is formed between a housing 710 and a display assembly 720 of an electronic device. The housing 710 includes a ledge 712 formed proximate an opening in the housing. The display assembly 720 is designed to be adhesively bonded to the ledge. The adhesive can form a barrier to liquids that makes the electronic device water-resistant. Conventional techniques for forming the adhesive bond between the housing 710 and the display assembly 720 include dispensing an adhesive 730 on the ledge 712 and then pressing the display assembly 720 into the opening to compress the adhesive 730 between the ledge 712 and the display assembly 720. However, these techniques are not ideal as the adhesive flow is determined by pressure differentials caused by moving the display assembly 720 into the opening of the housing, and, as a result, the adhesive flow can be unpredictable. For example adhesive may flow out into the interior volume of the electronic device as opposed to up around the display assembly to fill a gap between the display assembly 720 and the edge of the housing 710.

As depicted in FIG. 7B, the magnetic adhesive 730 can be influenced by a magnetic field to flow up around the display assembly 720 and into the gap between the display assembly 720 and the housing 710. Rather than pressing the display assembly 720 into the opening to cause the adhesive to flow based on pressure differentials, the display assembly 720 can be moved into the opening much more gently at the same time that a magnet 240 is placed proximate the gap between the display assembly 720 and the housing 710. The magnetic adhesive 730 will then flow up around the display assembly 720 based on the influence of the magnetic field generated by the magnet 240. The adhesive bond between the display assembly 720 and the housing 710 formed using this technique is more uniform than conventional adhesive bonds formed using a pressure differential to flow the adhesive, which produces a better seal with less chance of developing a leak when the adhesive bond is also utilized to form a water-tight seal between the housing 710 and the display assembly 720 of the electronic device.

It will be appreciated that the technique illustrated in FIGS. 7A-7B is not limited to a joint between a housing and a display assembly of an electronic device, but is applicable generally to a joint formed between any two components. Furthermore, the techniques described herein can be utilized to form any adhesive bond shaped by a magnetic field. For example, the techniques can be applied to consumer electronic devices, industrial devices, mechanical assemblies, and circuit components placed on a printed circuit board. For example, the magnetic adhesive can be utilized to improve the strength of an adhesive bond used to stake electronic components such as a capacitor or integrated circuit package to a PCB. The increased strength of these adhesive bonds can improve the shock rating or vibration handling of the electronic components of a device.

FIG. 8 illustrates a portable electronic device 800, in accordance with some embodiments. As depicted in FIG. 8, the portable electronic device 800 includes a housing 802 having an opening on a front surface of the housing 802. A display assembly 804 is disposed in the opening in the housing 802. The display assembly 804 can include a means for presenting visual information such as a layer of liquid crystal display (LCD) elements or a layer of organic light emitting diodes (OLED). The display assembly 804 can also include a touch sensor, such as a capacitive touch sensor for detecting touch input on a surface of the display assembly 804.

In some embodiments, the portable electronic device 800 includes a protective covering overlaid on a top surface of the display assembly 804. The protective covering can comprise a layer of glass. The portable electronic device can also include an input element 806 such as a button or touch-sensitive surface. The input element 806 can be accessible through an opening of the protective covering.

The portable electronic device 800 can take the form of a tablet computer or mobile phone (e.g., cellular phone). In some embodiments, the housing 802 of the portable electronic device 800 includes a ledge, such as ledge 712, within the front opening of the housing 802. The display assembly 804 can be bonded to the ledge using the technique described above in reference to FIGS. 7A and 7B to cause the magnetic adhesive 730 to flow into a gap between the housing 802 and the display assembly 804.

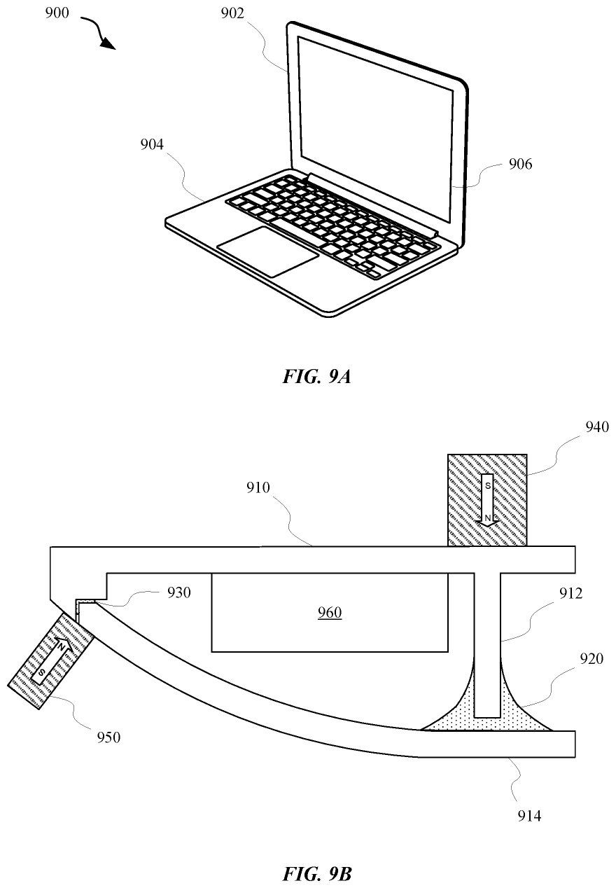

FIGS. 9A-9B illustrate a laptop computer 900 that utilizes a fastener free securing mechanism, in accordance with some embodiments. As depicted in FIG. 9A, the laptop computer 900 includes a top portion 902 and a base portion 904. The top portion 902 includes a housing having an opening. A display assembly 906 is secured in the opening of the housing included in the top portion 902. The base portion 904 includes a housing that defines an internal volume. Functional components of the laptop computer 900 including, but not limited to, a processor, memory, antennas, radio frequency transceivers, an energy storage device, one or more printed circuit boards, and the like can be secured within the internal volume. The base portion 904 can also include input devices such as a keyboard and/or a trackpad secured to the housing and accessible through a top surface of the base portion 904.

During assembly, the functional components are typically secured within the housing of the base portion 904 and then a cover is fastened to the housing to close the opening into the internal volume to protect the functional components disposed therein. The look and feel of a laptop computer can be important as a decision factor when customers are making a purchasing decision. Consequently, one goal of a manufacturer of the laptop computer can be to improve the industrial design of the laptop computer. One way that the industrial design may be improved is to remove the amount of visible fasteners from external surfaces of the housing.

As depicted in FIG. 9B, a component 914 is secured to a support structure 912 within the internal volume of the housing 910 of the base portion 904 of the laptop computer 900 using a fastener free securing mechanism. In some embodiments, the support structure 912 comprises a rib formed in the housing 910. Conventionally a screw or other mechanical fastener would be used to secure the component 914 to the support structure 912 by passing the mechanical fastener through a through hole formed in the component 914 and engaging the mechanical fastener with the support structure 912. In contrast, the fastener free securing mechanism encloses the fastening means on an internal side of the component 914 such that the fastening means is not visible from an external surface of the component 914.

In some embodiments, the fastener free securing mechanism includes a cured magnetic adhesive 920 that secures the support structure 912 to the component 914. The magnetic adhesive 920, prior to being cured, is characterized as having ferromagnetic particles dispersed within a liquid adhesive material, the ferromagnetic particles having a size and shape conducive to facilitating a flow of the liquid adhesive material in accordance with a magnetic field. The magnetic adhesive 920 can be similar to the magnetic adhesive 100, described above. A magnet 940 placed on a surface of the housing 910 during assembly generates the magnetic field proximate the joint between the component 914 and the support structure 912. The cured magnetic adhesive 920 forms a fillet on at least one side of a joint between the component 914 and the support structure 912.

The joint formed between the component 914 and the support structure 912 can be displaced, possibly significantly, from a seam between the component 914 and the housing 910 that is visible from the external surface of the component 914. Consequently, the magnetic adhesive 920 is dispensed on the internal surface of the component 914 prior to bringing the component 914 proximate the housing 910. The magnet 940 can be placed on the housing 910 subsequent to the component 914 being brought proximate the housing 910. Alternatively, the magnet 940 can already be in place prior to the component 914 being brought proximate the housing 910.

It will be appreciated that the cured magnetic adhesive 920 forms a fillet on at least one side of a joint between the component 914 and the support structure 912. A shape of the fillet is dependent on a strength of the magnetic field generated by the magnet 940 as well as a location of the magnet 940 relative the joint and a material of the housing 910, support structure 912, and component 914 as well as any other components located proximate the joint, such as functional component 960. The magnetic field can be adapted to result in a desired fillet shape. The desired fillet shape can be designed to accommodate additional components around the joint. For example, the functional component 960 could be a trackpad component that is secured to the housing 910 proximate the support structure 912. Consequently, the shape of the fillet should be adapted to prevent interference with the functional component 960, including the prevention of accidentally adhering the functional component 960 to the support structure, which could make servicing the laptop computer 900 more difficult.

In some embodiments, the seam between the component 914 and the housing 910 can also be sealed with a magnetic adhesive 930. Similar to the process described in FIGS. 7A-7B, the magnetic adhesive 930 can be dispensed on a surface of the housing 910 and then caused to flow into the seam by placing a magnet 950 proximate the external surface of the component 914 and/or housing 910 proximate the seam. The magnetic adhesive 930, once cured, can create a barrier to entry for liquids into the internal volume of the housing 910.

It will be appreciated that, in other embodiments, the component 914 secured to the support structure 912 can be enclosed within the internal volume of the housing 910 by a separate cover fastened to the housing 910. In other words, the component 914 secured to the support structure 912 can be an internal component that is not visible on any external surface of the laptop computer 900. In other embodiments, the component 914 can comprise the display assembly 906 secured to a housing of the top portion 902 of the laptop computer 900.

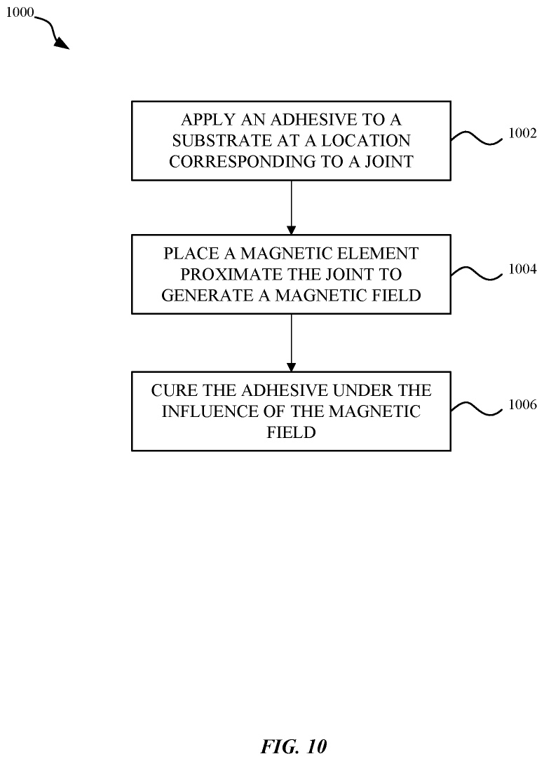

FIG. 10 is a flowchart of a method 1000 for forming an adhesive bond at a joint between components of a housing for an electronic device, in accordance with some embodiments. The method 1000 can be implemented using a fixture including a magnetic element and, optionally, an inductive heating element. In some embodiments, the fixture can be automated using one or more actuators controlled by a control system.

At 1002, an adhesive is applied to a substrate at a location corresponding to a joint formed between the substrate and a component. The adhesive includes magnetic particles dispersed therein. In some embodiments, the adhesive is in a liquid state having a viscosity sufficient to enable the adhesive to flow responsive to movement of the magnetic particles acting under the influence of a magnetic field.

At 1004, a magnetic element is placed proximate the joint to generate a magnetic field. The magnetic field interacts with the magnetic particles in the adhesive to cause the adhesive to flow in a direction corresponding to the magnetic field. In some embodiments, the magnetic element is a permanent magnet. In other embodiments, the magnetic element is an electromagnet.

At 1006, the adhesive is cured under the influence of the magnetic field. The adhesive transitions from a liquid state to a solid state to form an adhesive bond at the joint having a shape that is determined, at least in part, by the strength and orientation of the magnetic field proximate the joint.

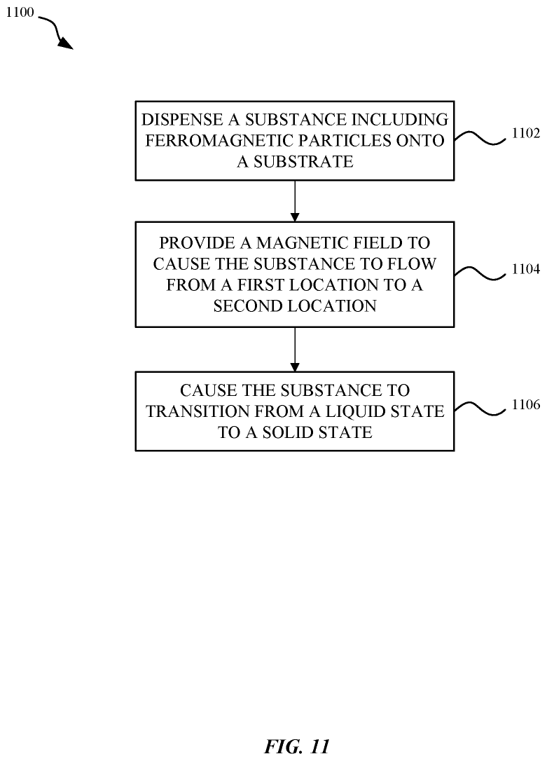

FIG. 11 is a flowchart of a method 1100 for influencing a magnetic substance using a magnetic field, in accordance with some embodiments. The method 1100 can be practiced with any liquid substance that can transition to a solid state and exhibits characteristics, in the liquid state, that are sufficient to promote controlled flow of the liquid substance responsive to motion of the magnetic particles dispersed in the liquid substance.

At 1102, a substance including magnetic particles is dispensed onto a substrate. In some embodiments, the substance is dispensed in a liquid state and exhibits a viscosity in the liquid state of at least 10,000 cP. The substance can include ferromagnetic particles at a concentration of at least 20 percent by weight, the particles having a major dimension less than 200 micrometers in length.

At 1104, a magnetic field is provided to cause the substance to flow from a first location to a second location. The substance flows towards the source of the magnetic field under the influence of an attractive force experienced by the magnetic particles dispersed in the substance that causes the magnetic particles to more towards the source of the magnetic field.

At 1106, the substance undergoes a transition from a liquid state to a solid state under the influence of the magnetic field. In some embodiments, the state transition is caused by introduction of radiation (e.g., UV light) or heat to the substance. In other embodiments, the state transition occurs over a period of time after being exposed to the environment (e.g., air) or in response to a natural chemical reaction that occurs between the components of the substance. In some embodiments, the magnetic field can be reduced or removed once the substance reaches a gel point where cross-linking in the polymers of the substance result in a significant increase in the viscosity of the liquid.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a non-transitory computer readable medium. The non-transitory computer readable medium is any data storage device that can store data which can thereafter be read by a computer system. Examples of the non-transitory computer readable medium include read-only memory, random-access memory, CD-ROMs, HDDs, DVDs, magnetic tape, and optical data storage devices. The non-transitory computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A structural assembly comprising:
a substrate;
a component having at least one surface placed proximate a bonding surface of the substrate; and
a magnetic adhesive bonded to the at least one surface and the bonding surface, the magnetic adhesive including particles of a magnetic material that, when subjected to a magnetic field while the magnetic adhesive is in an uncured state, form a joint between the substrate and the component having a shape corresponding with the magnetic field.

2. The structural assembly of claim 1, wherein the particles include ferromagnetic particles.

3. The structural assembly of claim 1, wherein the shape comprises a fillet on a first side of the component, the first side being arranged substantially perpendicular to the bonding surface of the substrate.

4. The structural assembly of claim 3, wherein the shape comprises a second fillet on a second side of the component, the second side being arranged substantially perpendicular to the bonding surface of the substrate.

5. The structural assembly of claim 1, wherein the structural assembly comprises a housing of a portable electronic device.

6. The structural assembly of claim 1, wherein the magnetic adhesive, in an uncured state, includes a liquid polymer having a viscosity in the range of 10,000 to 30,000 centipoise.

7. An electronic device formed using an adhesive bond to join at least two structural components, the electronic device comprising:
a first component; and
a second component bonded to the first component by a magnetic adhesive to form a joint between the first component and the second component,
wherein a shape of the magnetic adhesive, as cured at the joint, is based on a magnetic field imparted at the joint during assembly while the magnetic adhesive is in an uncured state.

8. The electronic device of claim 7, wherein the magnetic adhesive comprises magnetic particles dispersed in a non-magnetic liquid polymer.

9. The electronic device of claim 8, wherein the magnetic particles comprise a ferromagnetic metal.

10. The electronic device of claim 8, wherein the magnetic particles comprise a non-ferromagnetic core coated in a ferromagnetic metal.

11. The electronic device of claim 8, wherein the liquid polymer is cured using an inductive heating element to generate heat in the magnetic particles.

12. The electronic device of claim 7, wherein the first component comprises a housing of the electronic device, the housing including an opening in a front surface of the housing, and wherein the second component is a display assembly, disposed in the opening

13. The electronic device of claim 12, wherein the second component is a display assembly, disposed in the opening, and the magnetic adhesive provides a water-resistant seal between the display assembly and the housing.

14. The electronic device of claim 12, wherein the second component is a structural component, disposed in an internal volume of the housing defined by the opening.

15. A method of applying adhesive to a joint formed between a substrate and a component, the method comprising:
applying an adhesive to a substrate at a location corresponding to the joint, wherein the adhesive includes magnetic particles dispersed therein;
placing a magnetic element proximate the joint to generate a magnetic field that interacts with the magnetic particles in the adhesive to cause the adhesive to flow in a direction corresponding to the magnetic field; and
curing the adhesive under an influence of the magnetic field.

16. The method of claim 15, further comprising removing the magnetic element once the adhesive reaches a gel point.

17. The method of claim 15, further comprising adjusting a strength of the magnetic field generated by the magnetic element corresponding to a desired shape of the adhesive at the joint.

18. The method of claim 15, wherein the magnetic element comprises a permanent magnet.

19. The method of claim 15, wherein the magnetic element comprises an electromagnet.

20. The method of claim 15, wherein curing the adhesive comprises heating the magnetic particles using an inductive heating element.
